(19) United States
(12) Patent Application Publication
(10) Pub. No.: US 2013/0058017 A1
(43) Pub. Date: Mar. 7, 2013

(54) CASE FOR AN AUDIO DEVICE

(71) Applicants: Mardis Bagley, San Francisco, CA (US); John Cataldo, Westlake Village, CA (US); Daniel C. Sullivan, Santa Barbara, CA (US)

(72) Inventors: Mardis Bagley, San Francisco, CA (US); John Cataldo, Westlake Village, CA (US); Daniel C. Sullivan, Santa Barbara, CA (US)

(73) Assignee: HeadLogic LLC, Westlake Village, CA (US)

(21) Appl. No.: 13/405,132

(22) Filed: Feb. 24, 2012

Related U.S. Application Data
(60) Provisional application No. 61/447,816, filed on Mar. 1, 2011.
(60) Provisional application No. 61/535,629, filed on Sep. 16, 2011.

(51) Int. Cl. H05K 5/03

(52) U.S. Cl. 361/679.01

(57) ABSTRACT

A case for holding an audio device includes a cover having two sections that interconnect to encase an audio device. The case also includes a means for electrically connecting the cover to an audio device, and a contact pad mounted on the cover capable of electrically connecting the case with a cartridge for managing ear bud cables. The means for electrically connecting may include a female audio jack, an apple thirty pin connector, a universal serial bus connector, or a high definition multimedia interface connector.

### PRIORITY CLAIM

This patent application claims priority to U.S. Provisional Patent Application No. 61/447,816, filed 1 Mar. 2011, and to U.S. Provisional Patent Application No. 61/535,629, filed 16 Sep. 2011, the disclosures of these provisional patent applications are incorporated herein by reference.

### FIELD OF THE INVENTION

The present invention relates to cases for audio devices, including cases designed for use with an ear bud management mechanism that dispenses and retracts ear bud cables.

### BACKGROUND OF THE INVENTION

Ongoing research indicates a relationship between prolonged exposure to cell phone radiation and illness including cancer. The risk of illness decreases significantly where cell phones are used at a distance from the user. Positioning a cell phone even a few inches away the ear can greatly reduce harm from cell phone radiation.

There are several ways to manage the health risks associated with prolonged cell phone use. One way is to use a speakerphone and hold the phone at a distance. However, many do not want their phone conversations overheard, or to disturb others with a loud two way conversation. Additionally, prolonged use of the speakerphone can greatly reduce battery life.

Another way to reduce health risks associated with cell phone use is to use a Bluetooth headset. The energy radiated by a phone with a typical Bluetooth headset is orders of magnitude less than a cellular phone signal. Bluetooth technology requires sufficient power to communicate over a number of feet, where cell phone signals require sufficient power to communicate thousands of feet, and sometimes miles, between a cellular device and a distant cellular tower.

Yet another way to reduce health risks is to use a wired headset. Wired ear buds may, for example, insert into a user's ear, hang on the ear, or hang on the head. Ear buds are energy efficient and have lessened health risks due to radiation. When two ear buds are used, stereo sound is possible.

One major drawback of using wired ear buds with portable consumer electronics devices and telephones is cord management. Cord management is a commonly experienced problem where the cord of the ear buds becomes tangled and may be damaged by a frustrated user who attempts to hastily untangle the cord. Operating an automobile, a bicycle, or other vehicle while experiencing cord management problems can be dangerous. What is desired is a better way of cord management which enables the user to readily extend and retract ear bud cables in a rapid and reliable manner.

### SUMMARY OF THE INVENTION

The present invention includes a case attachable to a cartridge for managing ear bud cables. The cartridge includes a housing having an input jack, a hub, a rotatable spool and an ear bud cable that is selectively wrapped around the spool. The term “ear bud” as used herein includes any audio speakers that mount on the head or ear of a user, either outside the ear or within the ear of a user. The term “audio device” includes telephones, computers, electronic notebooks, book reader pads, audio players, recorders and the like.

The case is designed for holding an audio device. The case includes a cover having at least one connector for physically attaching the cover to a cartridge for managing ear bud cables. The case includes a first electrical contact pad mounted on the cover capable of electrically connecting the case with a cartridge for managing ear bud cables.

The case also includes a means for electrically connecting the cover to an audio device. Accordingly, when the case electrically connects to an audio device and to a cartridge, audio communication between the audio device and cartridge enabled.

In one embodiment, the means for electrically connecting the cover to an audio device includes a male audio jack.

In an alternate embodiment, the cover includes a base electrical contact pad. The male audio jack includes a base, a cable attached to the male audio jack extends through the case, and a base contact pad for electrically connecting the base with the second electrical contact pad of the cover.

In another embodiment, the means for electrically connecting the cover to an audio device includes a cable extending from the first electrical contact pad and an apple thirty pin connector attached to the case in electrical communication with the cable.

In yet another embodiment, the means for electrically connecting the cover to an audio device includes a cable extending from the first electrical contact pad and a universal serial bus connector attached to the case in electrical communication with the cable.

In yet another embodiment, the means for electrically connecting the cover to an audio device includes a cable extending from the first electrical contact pad and a high definition multimedia interface connector attached to the case in electrical communication with the cable.

It can be appreciated that any one embodiment, the invention can include features from other embodiments.

### BRIEF DESCRIPTION OF THE DRAWINGS

FIG. 1 shows a perspective view of a cartridge for managing ear bud cables in accordance with the present invention.

FIG. 2 shows a perspective view of the cartridge retracting an ear bud cable.

FIG. 3 shows an exploded perspective view of the cartridge.

FIG. 4 shows an exploded perspective view of a hub and spool in accordance with the present invention.

FIG. 5 shows a top view of an alternate embodiment of the cartridge.

FIG. 6 shows a side view of a hub and spool in accordance with the embodiment shown in FIG. 5.

FIGS. 7a, 7b, 7c and 7d show an exploded perspective view of a cartridge and various embodiments of the case.

FIG. 8 shows a bottom perspective view of the bottom of the cartridge.

FIG. 9 shows a side perspective view of a cartridge and a case in transverse alignment.

FIG. 10 shows a reverse-side perspective view of the cartridge and case of FIG. 9.

FIG. 11 shows an exploded perspective view of the case of FIG. 10.

### DETAILED DESCRIPTION

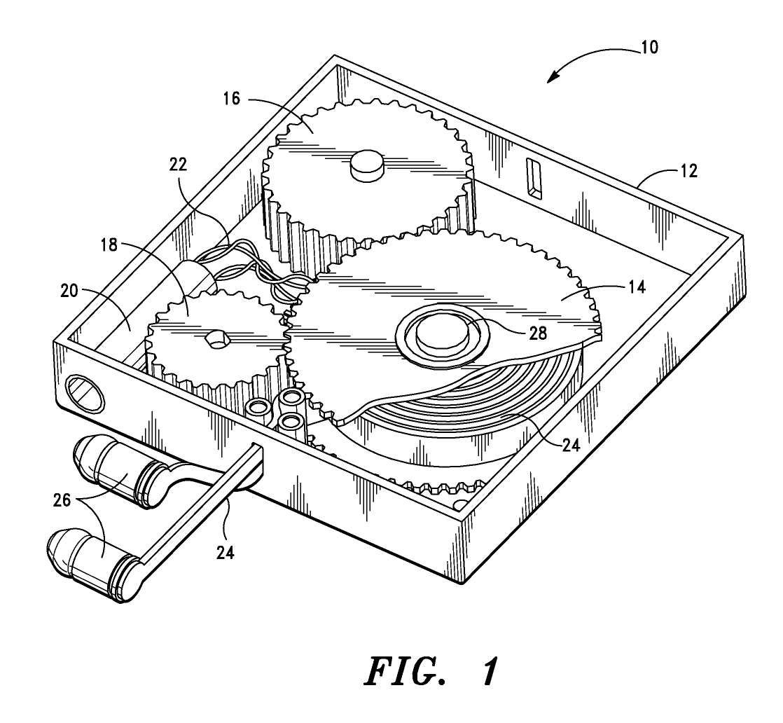

FIG. 1 is a cartridge generally designated by the reference numeral 10. The cartridge 10 includes housing 12, a spool 14, a power gear 16, a rotary damper gear 18, an input jack 20, an electrical connector 22, an ear bud cable 24, ear buds 26 and a hub 28.

The hub 28 is fixed within the housing 12. The spool 14 rotatably mounts on the hub 28. Rotation of the spool 14 dispenses and retracts the ear bud cable 24 from the housing 12.

The rotary damper gear 18 is rotatably mounted within the housing 12. The rotary damper gear 18 mates in operative engagement with the spool 14 so that the rotary damper gear 18 presses against the spool 14. In particular, both the rotary damper gear 18 and the spool 14 each have a periphery. The periphery of the rotary damper gear 18 and the periphery of the spool 14 press against each other in a direction tangential to the respective peripheries, and may press against each other in a radial fashion. The rotary damper gear 18 and the spool 14 mate so that free rotation of the spool 14 is inhibited by the rotary damper gear 18.

In this way, the rotary damper gear 18 limits the maximum angular velocity of the spool 14. Limiting the angular velocity of the spool 14 protects the cartridge 10 from damage. Limiting the angular velocity of the spool 14, in cooperation with the rotary damper gear 18 pressing against the spool 14 inhibits misalignment of the spool 14 to maximize durability of the cartridge 10. Preferably the rotary damper gear 18 and the spool 14 include peripheral gear teeth which mate to further improve alignment to optimize movement of the moving components, and improve cartridge 10 reliability.

When gear teeth are used, improved tangential pressure is achieved between the spool 14, the rotary damper gear 18 and the power gear 16. An element of radial force is also applied between these elements when one of the elements misaligns. Thus the function of the gears includes maintaining alignment of the spool 14. Improved alignment of the spool increases the reliability of the cartridge 10.

Although the use of the power gear 16 in a rotary damper gear are disclosed here in it can be appreciated that many ways of providing power to the spool 14 can be devised. Furthermore many ways of regulating the angular velocity of the spool 14 can also be provided. For example at dampening mechanism may include a leaf spring mounted within the housing which presses on the peripheral surface of the spool 14 can create sufficient frictional force to dampen rotation of the spool 14.

Additionally a power mechanism such as a spiral power spring can be mounted on the housing with respect to the spool 14 so that the spring directly contacts the spool 14 and thereby powers the spool.

Furthermore, linkages such as a chain, a belt, or other mechanical transmission mechanism can be used to regulate rotation of the spool.

The ear bud cable 24 wraps at least partially around the spool 14. The ear bud cable 24 as a first end attached within the spool and a second and attached to ear buds 26. The ear bud cable 24 is flat to optimize alignment of the cable 24 within the spool 14 when the cable is retracted and dispensed. Utilizing a flat cable 24 minimizes the thickness of the cable to maximize the length of the cable that can be wrapped around the spool 14. The flat cable 24 minimizes entanglement of the cable 24, as compared to the use of a round cable.

The cartridge 10 utilizes the power gear 16 to selectively rotate the spool 14, or to assist in spool 14 rotation. The power gear can be externally actuated by a switch operated by a user, or by pulling the cable 24 in the way traditional window shade works. In particular, a quick pull of the cable 24 causes the power gear and the spool 14 to retract the cable 24, and a slower pull of the cable 24 enables the power gear and the spool to dispense the cable 24. The power gear 16 can be calibrated to assist in response a desired pressure applied on the cable 24.

Rotation of the power gear 16 in one direction retracts the cable 24. Counter rotation of the power gear 16 dispenses the cable 24. The power gear 16 has a periphery which presses against the periphery of the spool. Preferably the power gear 16 has peripheral gear teeth which mate with the peripheral gear teeth of the spool 14 to improve alignment and reliability of the cassette 10. The power gear 16 is spring biased to apply consistent torque to the spool 14. Applying consistent torque to the spool 14 helps to maintain a relatively constant angular velocity of the spool 14. The cooperation of the power gear 16 and the rotary dampening gear 18 assure that a constant angular velocity of the spool 14 will be achieved to cartridge 10 reliability.

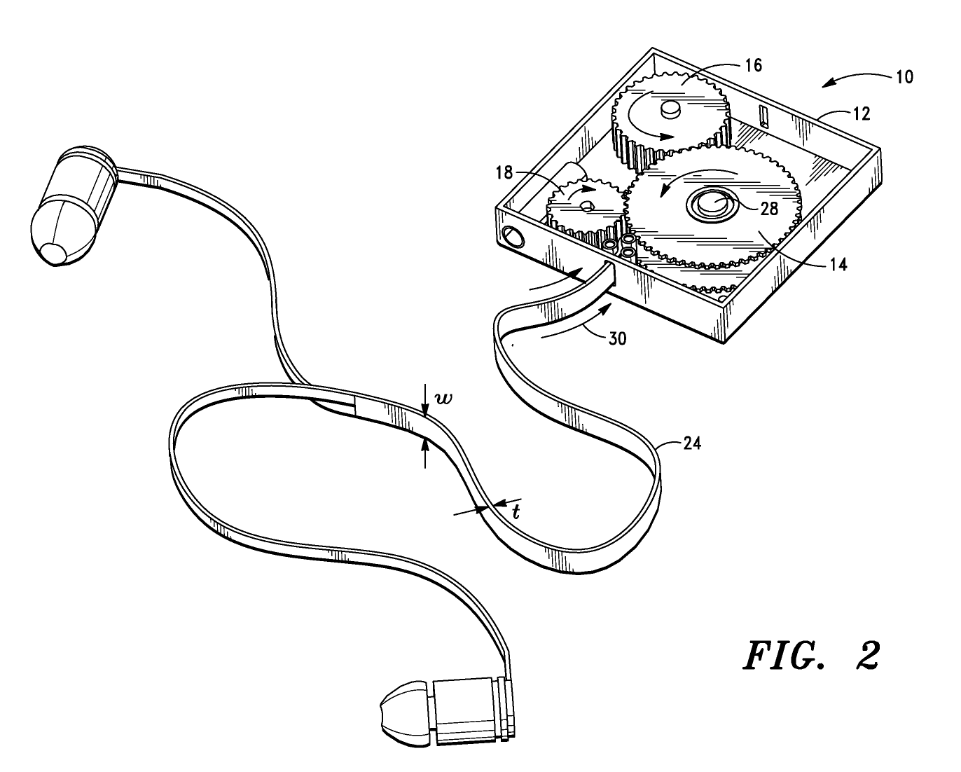

FIG. 2 shows rotation of the power gear 16 causing counter rotation of the spool 14, which retracts ear bud cable 24 in the direction of the arrow 30. The rotary damper gear 18 rotates in response to rotation of the spool 14 to regulate the angular velocity of the spool 14 as well as the rate of retraction of the ear bud cable 24. Regulation of the rate of retraction of the ear bud cable 24 increases reliability of the cartridge 10 by inhibiting misalignment of the cable 24 within the spool 14.

Although the rotary damper gear 18 and the power gear 16 are shown as separate elements, it can be appreciated that the function of these two elements can be combined into a single element to minimize size and weight of the cartridge 10.

The cable 24 has a width “w” and a thickness “t”. The cable 24 is flat and the thickness “t” is thinner than half of the width “w”. Preferably, the thickness “t” is minimized to enable cartridge 10 to maximize the amount of cable 24 that can be managed by the cartridge 10.

The cable 24 preferably includes a microphone for use with telephonic applications. The microphone enables the input jack to simultaneously function as an output jack.

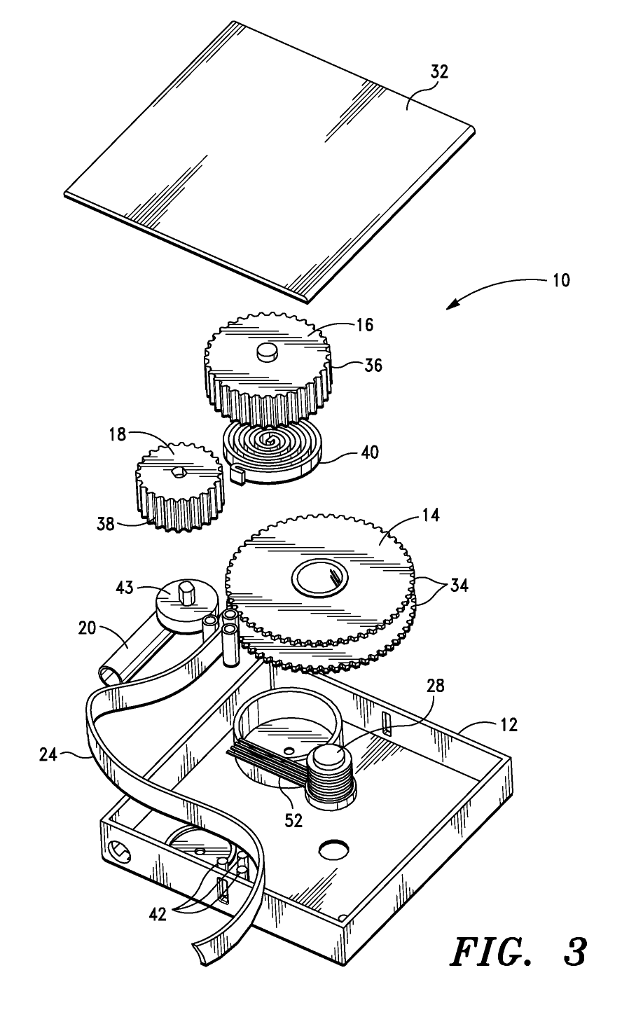

FIG. 3 shows the cartridge 10 including the housing 12 and a cover 32, which encloses the housing 12. The housing includes a hub 28 fixed within the housing 12 the hub 28 is sized to receive the spool 14 in operative engagement. The hub 28 includes electrical connectors 52, which communicate electronically with the input jack 20.

The power gear 16 defines peripheral gear teeth 36 and includes a power gear spring 42 to actuate the power gear 16. The power gear spring 40 attaches to the housing 12 and to the power gear 16 to selectively apply torque to the power gear 16. Ideally, the torque would be uniform in magnitude.

When the power gear spring 40 applies torque to the power gear 16 the power gear 16 rotates the spool 14 to selectively retract or dispense the cable 24. When the spool 14 rotates the rotary damper gear 18 regulates the angular velocity of the spool 14 the rotary damper gear 18 includes gear teeth 38 defined on the periphery of the rotary damper gear teeth 38 meet with peripheral gear teeth 34 of the spool 14. In particular, the spool 14 has two sets of peripheral gear teeth 34 that parallel each other and simultaneously meet with the gear teeth 38 of the rotary damper gear.

The cartridge 10 also includes a rotary damper 43 attached between the housing 12 and the rotary damper gear 18. The rotary damper 43 is fixed within the housing 12 and includes a rotatable axle for receiving the rotary damper gear 18. The axle enables rotation of the rotary damper gear 18 on the axle. The rotary damper 43 regulates angular velocity the rotary damper gear 18 thus regulating angular velocity of the spool 14.

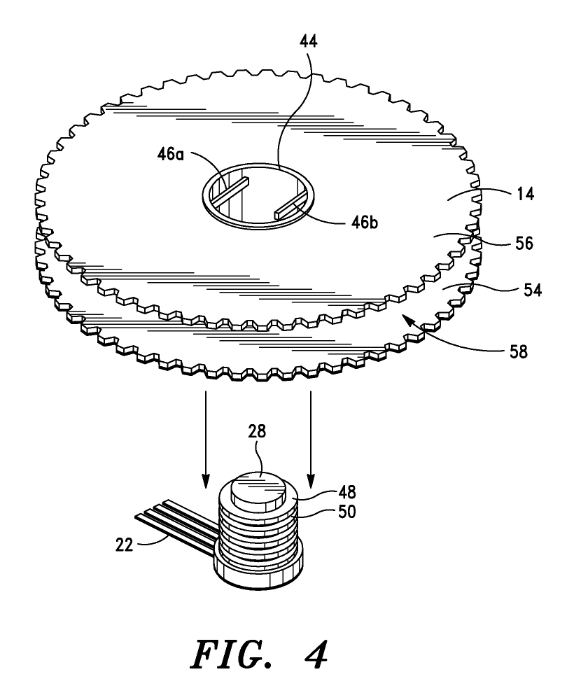

FIG. 4 shows the hub 28 and the spool 14. The spool 14 includes an inner periphery 44 defining an opening. The opening is defined axially on the spool 14. The spool 14 includes moveable audio contacts 46a and 46b. The movable audio contacts 46a and 46b extend radially inwards from the inner periphery 44 to enable the movable audio contacts 46a and 46b to establish a continuous electrical connection with the hub 28.

The moveable audio contacts 46a and 46b as shown are resilient conductive contacts and may, or may not, be pin shaped. The moveable audio contacts 46a and 46b may be metallic, but could also be formed from any suitable electrically conductive material. Preferably, the contacts 46a and 46b are made from copper coated with gold to improve conductivity.

The hub 28 is fixed within the housing and oriented to enable rotation of the spool 14. The hub 28 includes several electrical contacts 50. The electrical contacts 50 are ring shaped defining continuous annular rings which circumscribe the hub 28. The electrical contacts 50 are separated by several ring shaped circumferential ridges 48, which says circumscribe the hub 28 between each electrical contact 50. The ridges 48 assure that the electrical contacts 50 remain fixed with respect to the hub 28 when the 14 rotates on the hub 28. The ridges 48 further assure alignment of the spool 14 during operation. This improves the reliability of the cartridge 10. Preferably there are four contacts 50 with one to enable a ground, one to enable right speaker sound, one to enable left speaker sound and one to enable microphone function.

The hub 28 further includes electrical connectors 22 which extend hard-wired from each electrical contact 22 to the input jack 20 of FIG. 1.

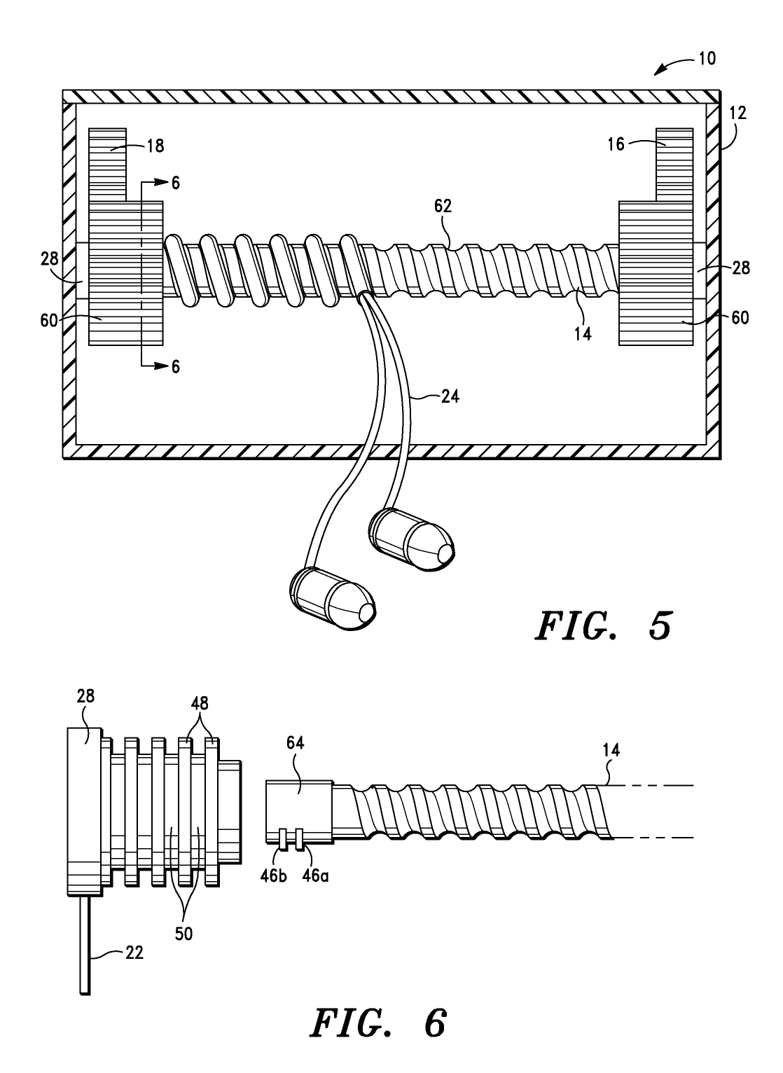

FIG. 5 shows an embodiment of cartridge 10 having a spool 14 mounted transversely across the housing 12. The housing 12 includes two hubs 28 and the spool 14 has two ends. Each end of the spool 14 rotatably mounts in a hub 28.

Preferably, the hubs 28 are stationary and define a central opening The ends of the spool insert within each hub 28 opening, respectively. In an alternate embodiment, the ends of the spool surround the hubs 28 and the hubs 28 insert into the ends of the spool.

Each end 60 of the spool 14 further includes gear teeth 62 to enable a power gear 16 and a rotary damper gear 18 to engage the spool 14.

The spool 60 is a spindle shape having a helical groove 62 for receiving the ear bud cables 24. A helical groove 62 is configured to optimally align and inhibit entanglement of the ear bud cables 24. The power gear 16 and the rotary damper gear 18 each engage a single end of the spool 14.

FIG. 6 shows an embodiment of the hub 28 receiving the end 64 of the spool 14. The end 64 includes movable audio contacts 46a and 46b. The hub 28 includes an electrical connector 22. The electrical connector 22 is hardwired to the contacts 50, which are inscribed within the hub 28. The contacts 50 are separated by circumferential ridges 48 to optimize alignment between the hub 28 and the school 14. The circumferential ridges 48 extend to the interior of the hub 28, which is hollow for receiving the end 64 of the school 14.

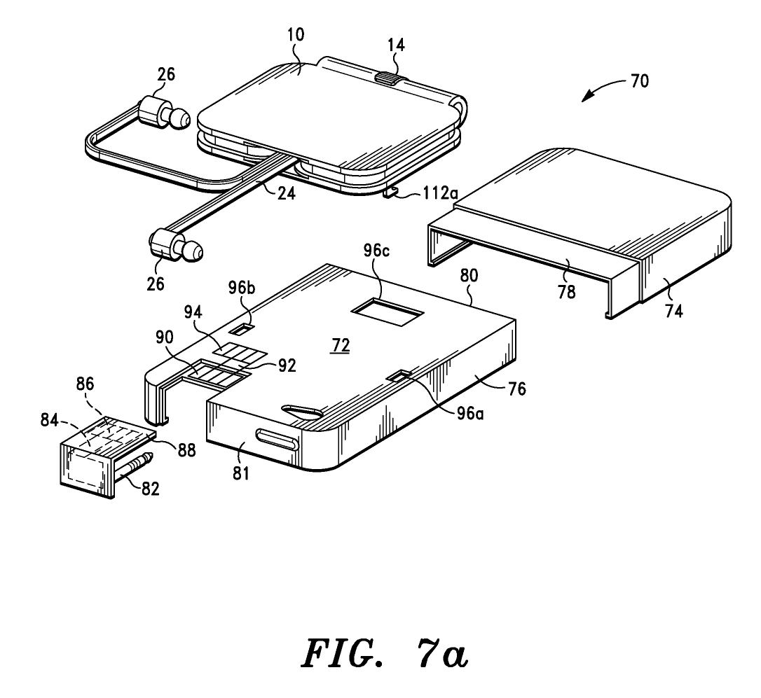

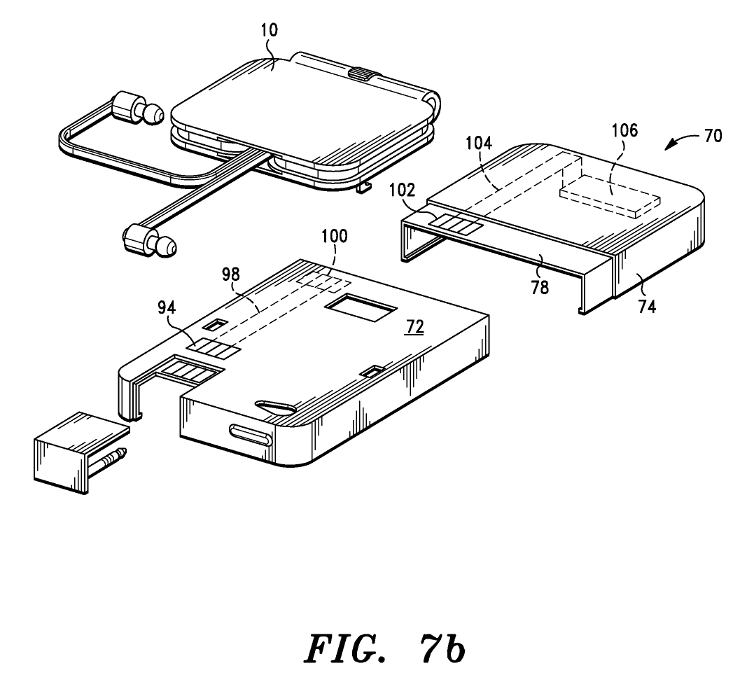

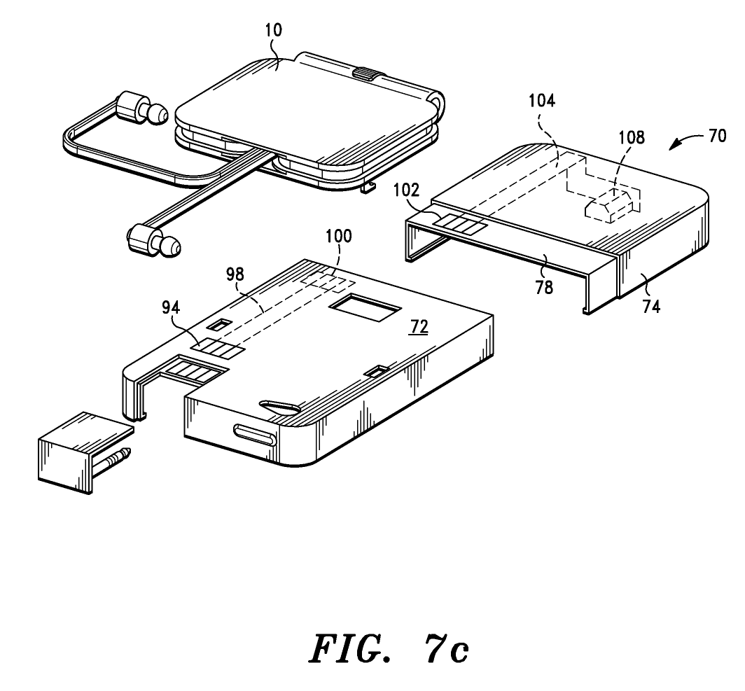

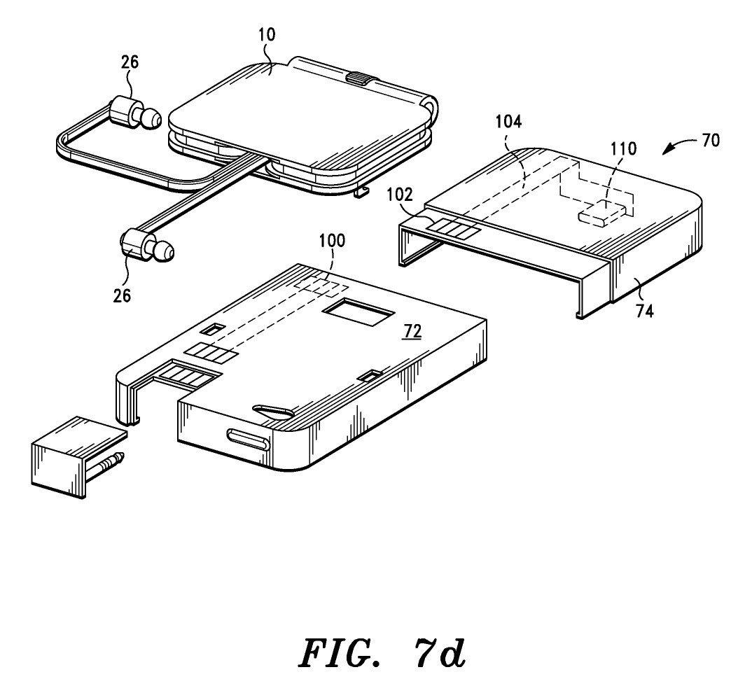

FIG. 7a shows an exploded view of the case 70 and a cartridge 10 for managing ear buds. The cartridge 10 includes ear bud cable 24 extending from the cartridge 10. The ear bud cable 24 is retractably mounted in the cartridge 10. The ear bud cable 24 has an end with two ear buds 26.

Preferably the ear buds 26 extend from one side of the cartridge 10, and that side of the cartridge aligns with the top end of an audio device cover.

The case 70 includes a cover 72 having two sections 74 and 76 that press-fit together to hold and protect an audio device. Preferably the audio device is a phone, portable music player, portable notebook or pad computer, or other device capable of playing music. As shown, the section 74 has a sleeve 78 that inserts into an end 80 of the section 76.

The cover 72 includes a top end 81 having a male audio jack 82 that removeably attaches in a press fit to the cover 72. The jack 82 includes a jack mount 88 having a flex cable 84 attached to the jack 82 and to an electrical contact pad 86 of the jack mount 88. The jack mount 88 removeably attaches to the cover 72 to enable selective connection between the jack 82 and a female audio jack of an audio device housed by the case 70.

The cover 72 includes an electrical contact pad 86 configured for receiving the contact pad 86 of the jack mount 88. A flex cable 92 interconnects the contact pad 86 with the contact pad 94. The contact pad 94 mounts on the section 76 of the cover end 70 to electrically connect the cover 70 with the cartridge 10.

The cover 70 includes three mounts 96a, 96b and 96c for attaching the cartridge 10 to the cover 70. Preferably the mounts 96a, 96b and 96c are recessed, forming openings in the cover 70. The mounts 96a, 96b and 96c cooperate to assure alignment between the cartridge 10 and the cover 70 so that audio communication between any audio device housed by the cover 70, and the cartridge 10 is enabled.

The cartridge 10 includes at least one connector 112a to interconnect the cartridge 10 with the cover 70. The cartridge 10 includes a release button 114 for selectively connecting and releasing the cartridge 10 from the cover 70.

It can be appreciated that the 94 includes four electrical contacts. One of the contacts powers the right ear bud and one powers the left ear bud to deliver stereo sound. One of the contacts is a ground. The fourth contact is to enable microphonic communication between a microphone affixed to the ear bud cable 24 and to any audio device held by the case 70.

FIG. 7b shows an embodiment of the cover 70 where the section 72 electrically connects with the section 74. The contact pad 94 includes a flex cable 98 and an end contact pad 100. The flex cable 98 electrically connects the contact pad 94 and the end contact pad 100. The end contact pad 100 exposes contacts inside the section 72 to enable the section 72 to electrically connect with the sleeve 78 of the section 74. The sleeve 78 includes a contact pad 102 that aligns with and electrically connects with the contact pad 100 when the section 72 and the section 74 press fit together.

The contact pad 102 includes a flex cable 104 and an Apple™ thirty pin connector 106 mounted at a base of the section 74. The flex cable 104 interconnects the contact pad 102 and the thirty pin connector 106 to enable the case 70 to electrically connect to an Apple™ product such as an I-Phone™ or an I-Pad™.

FIG. 7c shows the cartridge 10 and the case 70. The cover section 72 and the cover section 74 electrically interconnect via the contact pads 100 and 102, respectively. The flex cable 104 extends from the contact pad 102 to a universal serial bus connector (USB) 108 to enable the case 70 and the cartridge 10 to electrically connect with an audio device having a universal serial bus (USB) port.

FIG. 7d shows the cartridge 10 and the case 70. The cover section 72 and the cover section 74 electrically interconnect via the contact pads 100 and 102, respectively. The flex cable 104 extends from the contact pad 102 to a universal high definition multimedia interface (HMDI) 110 to enable the case 70 and the cartridge 10 to electrically connect with an audio device having a high definition multimedia interface (HMDI) port. Using n HMDI port enables encrypted contact to be communicated from any audio device via the case 70 to the cartridge 10 and ear buds 26.

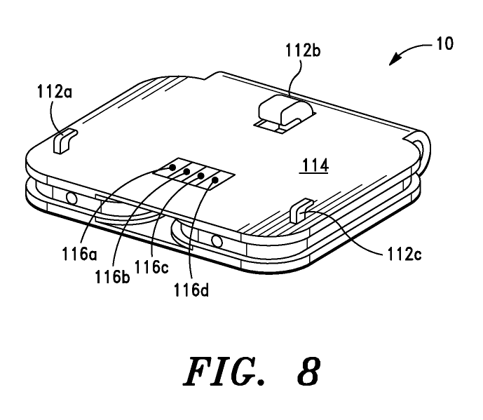

FIG. 8 shows the cartridge 10 from a bottom view. The cartridge 10 includes a bottom 114 and connectors 112a, 112b, and 112 c extending from the bottom 114 of the cartridge 10. The connectors 112a, 112b, and 112 each form hooks for attaching the cartridge 10 to the cover 70.

The connector 112b is moveable and extends and retracts to release and lock the cartridge 10 to the case 70 (FIG. 7a). Preferably the connector 112b mechanically connects to the release button 114 (FIG. 7a) to enable a user to selectively and rapidly disconnect the cartridge 10 from any audio device.

The bottom 114 of the cartridge 10 includes a four pin contacts 116a, 116b, 116c and 116d. The pin contacts 116a, 116b, 116c and 116d are spring-biased pins of copper coated with gold that are configured for mating in electrical connection with the contact pad 94 (FIG. 7a) when the cartridge 10 mounts on a case 70.

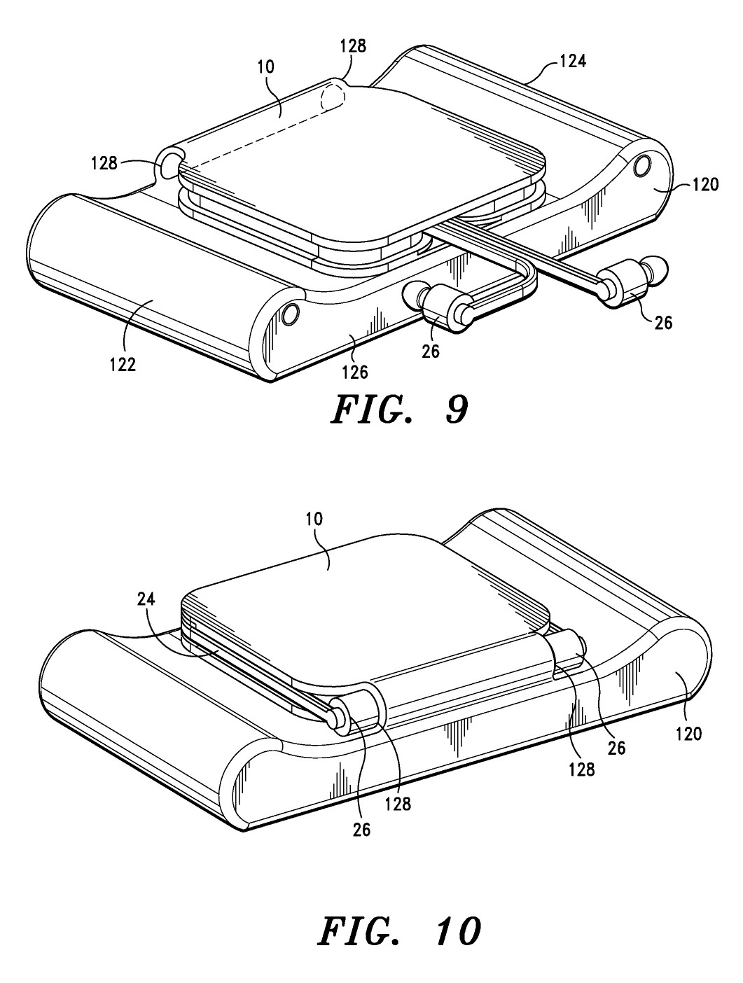

FIG. 9 shows a cartridge 10 mounted on a case 120. The case 120 has a top 122, a bottom 124 and a lateral side 126. The ear buds extend from the cartridge on the lateral side 126 of the case 120. The cartridge 10 includes a pair of ear bud collectors 128 that receive ear buds 26 in a press fit for storage. Preferably the ear bud collectors 128 form a tubular opening for receiving the ear buds 26. In one embodiment, the ear buds 26 are compressible to better facilitate the press fit within the ear of a user, and within the ear bud collectors 128.

FIG. 10 shows a cartridge 10 mounted on a case 120. The ear buds 26 each insert in a press fit into an ear bud collector 128 for storage and transport. Inserting the ear buds 26 into the ear bud collectors 128 inhibits entanglement of the ear bud cable 24.

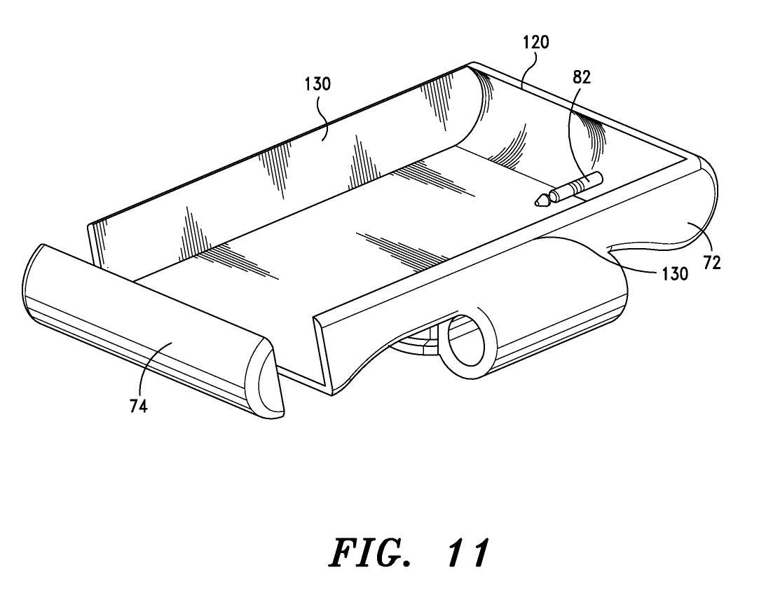

FIG. 11 shows a case 120 having a cover section 72 and a cover section 74. The cover section 74 is a cap that press-fits onto the cover section 72. The cover section 72 includes a male audio jack 72 that is fixed on the cover section 72. Accordingly, the cover section 72 has lateral sides 130 and is slidably mounted on an audio device so that the lateral sides 130 of the cover section 72 align the cover section 72 on the audio device and align the audio jack 72 with a female audio connector of the audio device.

While the present invention is disclosed in terms of various embodiments, including preferred embodiments, it can be appreciated that the true scope of the invention is defined only by the appended claims.

1. A case for holding an audio device, comprising:
a cover having at least one connector for attaching the cover to a cartridge for managing ear bud cables;
a first electrical contact pad mounted on the cover capable of electrically connecting the case with a cartridge for managing ear bud cables; and
a means for electrically connecting the cover to an audio device,
whereby when the case electrically connects an audio device to a cartridge for managing ear bud cables, audio communication between the audio device and cartridge is enabled.

2. A case as set forth in claim 1, wherein the means for electrically connecting the cover to an audio device includes a male audio jack.

3. A case as set forth in claim 2, wherein the cover includes a second electrical contact pad, the male audio jack includes a base, a cable attached to the male audio jack extending through the case, and a base contact pad for electrically connecting the base with the second electrical contact pad of the cover.

4. A case as set forth in claim 1, wherein the means for electrically connecting the cover to an audio device includes a cable extending from the first electrical contact pad and an apple thirty pin connector attached to the case in electrical communication with the cable.

5. A case as set forth in claim 1, wherein the means for electrically connecting the cover to an audio device includes a cable extending from the first electrical contact pad and a universal serial bus connector attached to the case in electrical communication with the cable.

6. A case as set forth in claim 1, wherein the means for electrically connecting the cover to an audio device includes a cable extending from the first electrical contact pad and a high definition multimedia interface connector attached to the case in electrical communication with the cable.

7. A case as set forth in claim 1, wherein the case has two sections that interconnect to encase an audio device.

8. A case as set forth in claim 1, wherein the case has two sections that press-fit with each other to encase an audio device.

9. A case as set forth in claim 1, wherein the case has two sections that press-fit with each other to encase an audio device and the means for electrically connecting the cover to an audio device includes a male audio jack affixed in one of the sections.

10. A case as set forth in claim 1, wherein a first electrical contact pad includes several flat pads that are electrically isolated from each other, the flat pads are capable of electrically connecting with spring loaded pins of a cassette for managing ear buds.

11. A case as set forth in claim 10, wherein the first electrical contact pad includes four flat pads to enable stereo audio signals to be communicated via the first electrical contact pad.

12. A case for holding an audio device, comprising:
a cover having two sections that interconnect to encase an audio device;
a means for electrically connecting the cover to an audio device;
a first electrical contact pad mounted on the cover capable of electrically connecting the case with a cartridge for managing ear bud cables.

13. A case as set forth in claim 12, wherein the means for electrically connecting the cover to an audio device includes a male audio jack.

14. A case as set forth in claim 12, wherein the cover includes a second electrical contact pad, the male audio jack includes a base, a cable attached to the male audio jack extending through the case, and a base contact pad for electrically connecting the base with the second electrical contact pad of the cover.

15. A case as set forth in claim 12, wherein the means for electrically connecting the cover to an audio device includes a cable extending from the first electrical contact pad, and an apple thirty pin connector attached to the case in electrical communication with the cable.

16. A case as set forth in claim 12, wherein the means for electrically connecting the cover to an audio device includes a cable extending from the first electrical contact pad and a universal serial bus connector attached to the case in electrical communication with the cable.

17. A case as set forth in claim 12, wherein the means for electrically connecting the cover to an audio device includes a cable extending from the first electrical contact pad and a high definition multimedia interface connector attached to the case in electrical communication with the cable.

18. A case as set forth in claim 12, wherein the means for electrically connecting the cover to an audio device includes a male audio jack affixed in one of the sections.

19. A case as set forth in claim 12, wherein the first electrical contact pad includes several flat pads that are electrically isolated from each other, the flat pads are capable of electrically connecting with spring loaded pins of a cassette for managing ear buds.

20. A case as set forth in claim 12, wherein the first electrical contact pad includes four flat pads to enable stereo audio signals to be communicated via the first electrical contact pad.
